(19) United States
(12) Patent Application Publication
(10) Pub. No.: US 2016/0288739 A1
(43) Pub. Date: Oct. 6, 2016

(54) ELECTRICAL SYSTEM

(71) Applicant: YAZAKI CORPORATION, Tokyo (JP)

(72) Inventors: Hideo TAKAHASHI, Makinohara-shi (JP); Eiji SHIMOCHI, Makinohara-shi (JP); Sadaharu OKUDA, Toyota-shi (JP); Hideaki KIKUCHI, Makinohara-shi (JP); Goro NAKAMURA, Makinohara-shi (JP); Naoya YAMASHITA, Toyota-shi (JP); Masahiro ITO, Makinohara-shi (JP)

(73) Assignee: YAZAKI CORPORATION, Tokyo (JP)

(21) Appl. No.: 14/777,590

(22) PCT Filed: Mar. 18, 2014
(86) PCT No.: PCT/JP2014/057376

§ 371 Date: Sep. 16, 2015

(30) Foreign Application Priority Data
Mar. 18, 2013 (JP) 2013-055420

(51) Int. Cl. B60R 16/02; H05K 7/02; B60L 11/18; B60R 16/03; B60L 11/02

(52) U.S. Cl. CPC B60R 16/0215; B60R 16/0207; B60R 16/03; B60L 11/02; B60L 11/18; H05K 7/02

(57) ABSTRACT

Joint portions (12A to 12H) are formed at a constant interval on a wire harness main body (10). Each joint portion has a common shape and function, and is configured of wires which are respectively branched from wires (11a to 11d) that configure the wire harness main body (10), and connectors (13A to 13H) which have connection terminals connected to the wires.

### TECHNICAL FIELD

The present invention relates to an electrical system which connects a plurality of modules to each other via a wire harness.

### BACKGROUND ART

In a vehicle, various electrical devices are disposed in a dispersed state at various locations on a vehicle body. For example, at each of the locations, such as a steering column, a glove box, a center cluster, or a center console, an electrical system related to travelling of the vehicle, an electrical system related to an audio, or an electrical system related to the functioning of the vehicle body, is disposed. Each of the electrical devices generally has various switches, various sensors, various loads, and a control relay mounted thereon.

It is necessary to supply power from a power source (an onboard battery or an alternator) on the vehicle side to various electrical devices. In addition, it is also necessary to transfer a signal of the switch or the sensor provided inside each of the electrical devices to another electrical device or various electronic control units (ECU) provided in the vehicle.

Therefore, in the related art, the power source on the vehicle side, various electrical devices, and various electronic control units are connected to each other via the wire harness. In general, the wire harness is configured by tying up multiple wires in a bundle. In addition, in order to make it possible to reliably connect instruments disposed at each part to each other, the length of each wire is adjusted and the shape of the wire harness is determined in accordance with a positional relationship of each instrument. In addition, in accordance with the amount of power which is consumed by the loads of each electrical device, the thickness of the electric power supply wire which configures the wire harness is determined. Furthermore, in order to make it easy to attach and detach electric connection between the wire harness and each instrument, a connector is connected to an end portion of each wire bundle which configures the wire harness.

In the electrical system disclosed in FIG. 1 of PTL 1, power is supplied by connecting a power source control box and various modules to each other by the wire bundles which are independent from each other. The entire wire harness is configured by further tying up the plurality of wire bundles in a bundle.

In addition, in PTL 2, a technology for simplifying wiring, reducing the weight of the wiring, and making it easier to perform wiring work is disclosed. Specifically, a plurality of submodules which are made by connecting a plurality of instrument panel electrical components to a common control unit is configured, the control unit of each submodule is connected to a common wire harness, and multiplex communication is performed between the plurality of control units.

In addition, in PTL 3, a technology for reducing the number of components and easily performing assembly and detachment is disclosed. Specifically, an instrument panel is formed by being divided into an upper panel and a lower panel, a concave portion to which a display and a meter are assembled is formed on the lower panel, and one pair of guide members and standby connectors 23 and 27 of the wire harness are provided in the concave portion.

### CITATION LIST

### Patent Literature

[PTL 1] JP-A-2012-56505

[PTL 2] JP-A-2000-38094

[PTL 3] JP-A-2004-189131

### SUMMARY OF INVENTION

### Technical Problem

In the above-described vehicular electrical system, it is required that the volume of the space which is occupied by the wire harness inside the vehicle body is reduced, or the weight of the wire harness is reduced. However, as disclosed in PTL 1, since the power is supplied by connecting the power source control box and various modules to each other by the wire bundles which are independent from each other, when the number of modules mounted on the vehicle increases, accordingly, the number of wire bundles which configure the entire wire harness increases, and it is inevitable that the thickness of the external shape of the wire harness increases.

In particular, regarding the power supply wire, it is necessary to use sufficiently thick wire so as to not cause a voltage drop and heat generation even when current which corresponds to the maximum value of the power consumed by the load of the module flows. In addition, when a distance from the power source to the module is long, it is necessary to dispose much thicker wire across the long distance since an increase in the voltage drop is expected.

In addition, when a possibility that a place where each module is disposed is changed in accordance with a change in specification or the like is expected, it is necessary to have room for the length of each wire which configures the wire harness so that wiring can be reliably connected even when the positions of each module are changed. However, when room for the lengths of the wires is determined to be large, inefficiency and the weight of the wire harness increase. Meanwhile, when room for length of the wire is small, there is a possibility that the wiring cannot be connected in a case where the positions of each module are changed, and a degree of freedom of a layout change deteriorates.

In consideration of the above-described situation, an object of the present invention is to provide an electrical system which can supply a sufficient amount of power to each module, and suppress an increase in the size of the external shape or the weight of a wire harness used in wiring, even when the number of modules including loads which consume a large amount of power increases.

### Solution to Problem

In order to achieve the above-described object, the electrical system according to the present invention has the following characteristics (1) to (3).

(1) An electrical system including: a module which has at least one of a switch, a sensor, a load, and a relay embedded therein;

a power source box portion which supplies power to the module; and

a wire harness which connects the plurality of modules and the power source box portion to each other, wherein

the power source box portion includes an electronic control portion that communicates with the module and controls the module,

the module includes a communication portion that communicates with the electronic control portion,

the wire harness is configured by tying up plural wires, including a power source line that transfers the power and a communication line that transfers a signal, in a bundle, and

joint portions, formed as each of the plural wires of the wire harness is branched and configured to be connected to the module, are formed at a plurality of locations on the wire harness at a substantially constant interval, in the wire harness.

(2) The electrical system configured according to the above-described (1), including: a first power source box portion and a second power source box portion as parts of the power source box portion,

wherein one end of the wire harness is connected to the first power source box portion, and the other end of the wire harness is connected to the second power source box portion.

(3) The electrical system configured according to the above-described (2), wherein

each of the joint portions is made as each of the plural wires of the wire harness is branched and extended, and a connector that includes the communication portion on the extended wires is connected thereto, and

the communication portion communicates with the electronic control portion when the connector is connected in the module.

According to the electrical system configured according to the above-described (1), the plurality of modules for transferring the power and the signal can use each of the plural wires that configures the wire harness in common. Therefore, even when the multiple modules are connected, it is not necessary to increase the number of wires that configure the wire harness, and it is possible to make the external shape of the entire wire harness to have a thin diameter. In addition, since it is possible to suppress all of the loads of the multiple modules so as to not consume the maximum power at the same time, even when the power is supplied to multiple modules via one wire, it is possible to suppress an increase in the diameters of individual wires in the wire harness. Furthermore, the joint portions are formed at the plurality of locations at a substantially constant interval, and thus it is possible to select the joint portion which connects each module as necessary. For example, when the positions of each module are changed in accordance with the change in specification of layout, it is possible to switch a connection point to a joint portion which is the closest to the position after the change. For this reason, even when room for the length of the wire harness at a location where the joint portion and each module are connected to each other is small, it is possible to reliably perform the connection if a joint portion having the shortest distance is selected.

According to the electrical system configured according to the above-described (2), by forming the joint portion by the connector, it is possible to simply perform work for joining the module to the wire harness.

According to the electrical system configured according to the above-described (3), it is possible to allocate a power supply function or a control function to the plurality of power source box portions in a dispersed state. Therefore, it is also possible to selectively supply the power from a power source box portion which is close to a module which consumes the power among the plurality of power source box portions, and to shorten a power transfer path. Accordingly, it is possible to make the wire which configures the wire harness to have a thin diameter.

### Advantageous Effects of Invention

According to the electrical system of the present invention, even when the number of modules which include the load that consumes a large amount of power increases, it is possible to supply sufficient power to each module, and to suppress an increase in the size of the external shape or the weight of the wire harness used in wiring.

Above, the present invention is briefly described. Furthermore, by reading through an embodiment for carrying out the invention (hereinafter, simply referred to as an “embodiment”) which will be described hereinafter with reference to the attached drawings, detailed contents of the present invention will become more apparent.

### BRIEF DESCRIPTION OF DRAWINGS

FIG. 1 is an electric circuit diagram illustrating a configuration example of an electric circuit of a main portion of an electrical system.

FIG. 2 is a plan view illustrating an example of connection between a power source control box and a wire harness main body.

FIG. 3 is a plan view illustrating a specific example of connection and disposition of the electrical system.

FIG. 4 is a block diagram illustrating a configuration of a plurality of modules and an example of connection with the power source control box.

FIG. 5 is a perspective view illustrating a specific example of an external shape of the power source control box.

### DESCRIPTION OF EMBODIMENTS

A specific embodiment regarding an electrical system of the present invention will be described hereinafter with reference to each drawing.

<Outline of Electrical System>

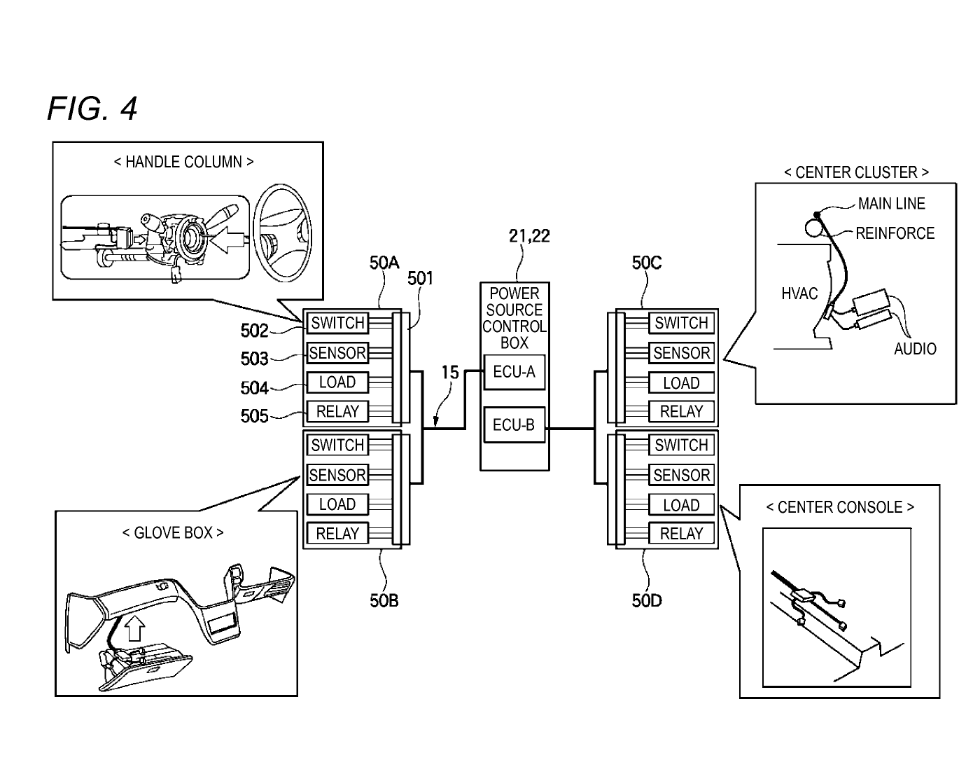

A configuration of a plurality of modules and an example of connection with a power source control box in the electrical system of the embodiment is illustrated in FIG. 4.

In the embodiment, the electrical system which is used being mounted on a vehicle is assumed. For example, in an example of the electrical system illustrated in FIG. 4, an electrical system in which power of a power source is supplied from a vehicle side to each of the plurality of modules 50A to 50D which are disposed in the vicinity of an instrument panel of the vehicle, and which has a function of controlling ON and OFF of loads in each module, is configured.

In addition, in the example of the electrical system illustrated in FIG. 4, the module 50A is installed in a handle column on the vehicle, the module 50B is installed in a glove box, the module 50C is installed in a center cluster, and the module 50D is installed in a center console.

In other words, the module 50A is configured as an integrated module which is configured of a switch 502, a sensor 503, a load 504, and a relay 505, which are disposed in the vicinity of the handle column. The switch 502, the sensor 503, the load 504, and the relay 505 are connected to an E connector portion 501 in the module 50A as illustrated in FIG. 4.

The E connector portion 501 is provided with a connector housing for connecting the module 50A and a wire harness 15 to each other, and an ECU which is stored and held in the connector housing. As the connector housing of the E connector portion 501 is fitted to a connection portion which is a fitting counterpart provided in the module 50A, the ECU of the E connector portion 501 is connected to the module 50A. The ECU in the E connector portion 501 has a function of controlling the switch 502, the sensor 503, the load (a lamp, a motor, a heater, or the like) 504, and the relay 505, and a function of communicating with the other control portion via the wire harness 15. In other words, the ECU in the E connector portion 501 controls ON and OFF of the load 504 and the relay 505 in accordance with a control signal received from an external control device by the communication. In addition, the ECU sends a signal which shows a state of the switch 502 or the sensor 503 to the external control device by the communication. The ECU in the E connector portion 501 can be configured of a microcomputer, for example. In this manner, the connectors which have a function of controlling the switch 502, the sensor 503, the load (a lamp, a motor, a heater, or the like) 504, and the relay 505 and a function of communicating with the other control portion via the wire harness 15 are generally called an E connector portion.

Similarly to the above-described module 50A, in each of other modules 50B to 50D, when the E connector portion 501 is connected, the ECU of the E connector portion 501 controls the switch 502, the sensor 503, the load 504, and the relay 505.

In the electrical system illustrated in FIG. 4, each of four modules 50A to 50D is connected to power source control boxes (21, 22) via the E connector portion 501 and the wire harness 15. The power source control box includes an electronic control unit (ECU) which has a function of supplying the power of the power source to each of the plurality of modules, and a function of controlling each of the plurality of modules, embedded therein.

In the example illustrated in FIG. 4, an electronic control unit (ECU-A) which controls modules of a travelling system and an audio system of the vehicle, and an electronic control unit (ECU-B) which controls a module of a body system, are provided in the power source control boxes (21, 22). The electronic control units (ECU-A, ECU-B) perform the communication with the E connector portion 501 of each module via the wire harness 15, switch ON and OFF of the power of each load (504), and obtain the signal of the switch (502) or the sensor (503).

<Description of Wire Harness Main Body>

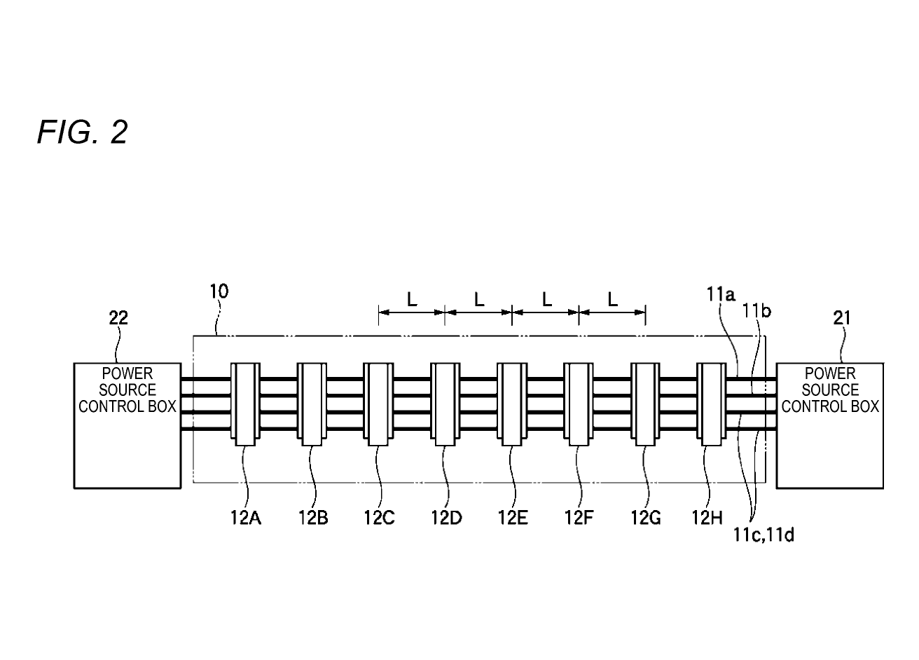

An example of the connection between the power source control box and the wire harness is illustrated in FIG. 2. In the example of the electrical system illustrated in FIG. 2, one end and the other end of a wire harness main body 10 which is a part of the wire harness 15 are respectively connected to the power source control boxes 21 and 22.

As illustrated in FIG. 2, the wire harness main body 10 is configured by tying up four wires 11a, 11b, 11c, and 11d which are electrically insulated from each other in a bundle. The wire 11a is used as a power source line for supplying DC power (for example, +12 V), the wire 11b is used as an earth line for earth connection, and the wires 11c and 11d are used as communication lines. The wires 11a and 11b have a core line which is configured of a semiconductor having a sufficiently thick diameter to the extent that a large amount of current can flow. The wires 11c and 11d are wires having a thin diameter since it is not necessary for a large amount of current to flow therein.

As illustrated in FIG. 2, in the wire harness main body 10, a plurality of joint portions 12A to 12H are formed at a substantially constant interval (L) from one end to the other end in a length direction. It is assumed that the interval (L) is determined to be 20 cm as a specific example.

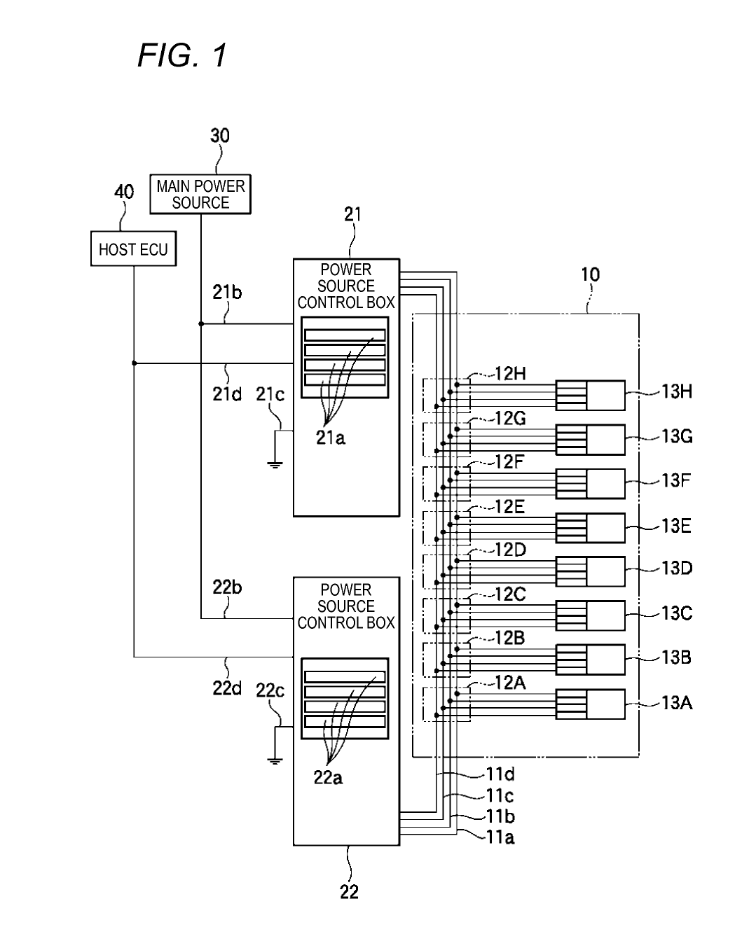

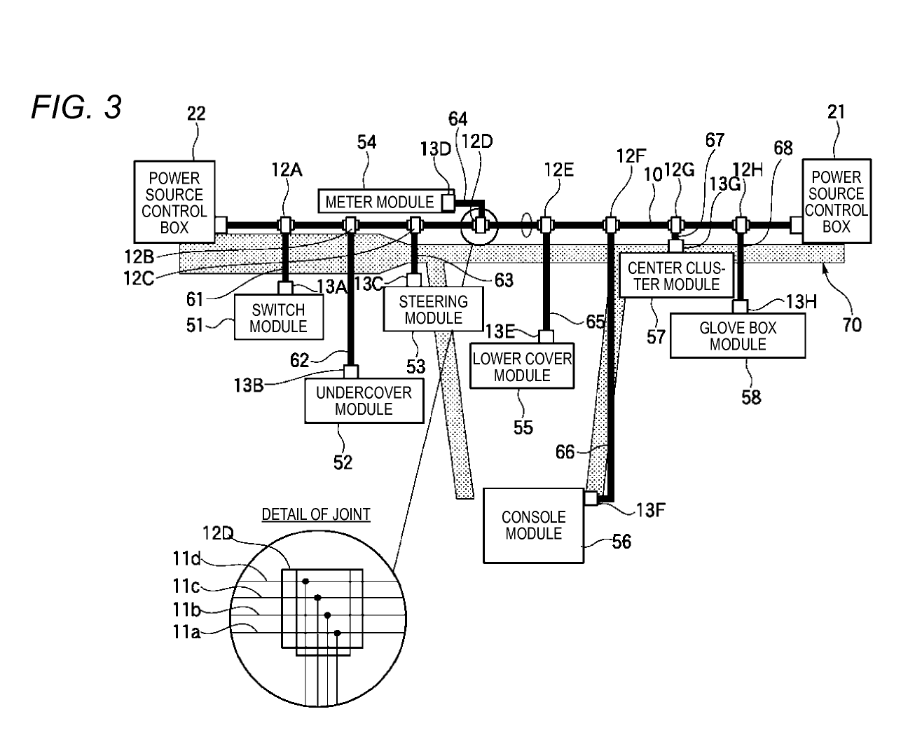

Each of the joint portions 12A to 12H can be used for connecting each module (51 to 58 in FIG. 3) as each of the four wires 11a, 11b, 11c, and 11d which configure the wire harness main body 10 is branched and extended. In other words, as illustrated in FIG. 1, in each of the joint portions 12A to 12H, branch points at which each of the wires 11a to 11d of the wire harness main body 10 is branched are formed. At four branch points where each of the wires 11a to 11d is branched in the joint portions 12A to 12H, the branched wires extend. Furthermore, connectors (13A to 13H) which include four connection terminals connected to each of the extended wires are connected to the wires. The four branched and extended wires correspond to module connection harnesses 61 to 68 illustrated in FIG. 3. In addition, each of the connectors 13A to 13H corresponds to the E connector portion 501 described with reference to FIG. 4. In this manner, each of the joint portions 12A to 12H are configured of four branched and extended wires and connectors.

Each of the plurality of joint portions 12A to 12H has a function which is common to each other except that the positions thereof are different from each other. In other words, each connector (13A to 13H) has the same shape, and each connector (13A to 13H) has four connection terminals which are electrically connected to each of the wires 11a to 11d.

<Specific Example of Connection and Disposition of Electrical System>

A specific example of connection and disposition of the electrical system is illustrated in FIG. 3. In the example of the electrical system illustrated in FIG. 3, various instruments disposed in the vicinity of the instrument panel of the vehicle are respectively connected to a plurality of locations of the wire harness main body 10 as the plural modules which are independent from each other.

In the example illustrated in FIG. 3, eight modules 51 to 58 are disposed in a state of being dispersed from each other at various locations in the vicinity of instrument panel. Similar to each module (50A to 50D) illustrated in FIG. 4, each of the modules 51 to 58 is connected to the E connector portion 501 (corresponds to the connectors 13A to 13H), and the ECU in the E connector portion 501 controls the switch 502, the sensor 503, the load (a lamp, a motor, a heater, or the like) 504, and the relay 505.

The module 51 has various switches which can be operated by an operator or the like. The module 52 has various configuration elements (a switch, a sensor, a lamp, a motor, and a relay) which are disposed in the vicinity of an undercover. The module 53 has various configuration elements (a switch, a sensor, a motor, and a relay for a direction indicator or a wiping device) which are disposed in the vicinity of a steering column. The module 54 has a configuration element for displaying various types of meters, such as a speedometer or an engine tachometer.

In addition, the module 55 has various configuration elements (a switch, a sensor, a lamp, a motor, and a relay) which are disposed in the vicinity of a lower cover. The module 56 has various configuration elements (a switch, a sensor, a lamp, a motor, and a relay) which are disposed in the vicinity of a center console. The module 57 has various configuration elements (an audio device and a navigation device) which are disposed in the vicinity of a center cluster. The module 58 has various configuration elements (a switch, a sensor, a lamp, a motor, and a relay) which are disposed in the vicinity of a glove box.

In the vicinity of the instrument panel and a center console of the vehicle body, as illustrated in FIG. 3, a reinforce 70 which is a stiffener is installed. The wire harness main body 10 is disposed in a straight line from a right end side to a left end side of the vehicle body along the reinforce 70. In addition, the right end of the wire harness main body 10 is connected to the power source control box 21 which is installed on the right end side of the vehicle, and the left end of the wire harness main body 10 is connected to the power source control box 22 which is installed on the left end side of the vehicle body.

In the example illustrated in FIG. 3, the module 51 is connected to the joint portion 12A. Specifically, the module 51 is connected to the connector 13A which is attached to a tip end of the module connection harness 61 that is branched from the wire harness main body 10 and extended. The module 51 is connected to the joint portion 12A which exists at the closest position among the plurality of joint portions (12A to 12H).

Similarly, the module 52 is connected to the joint portion 12B which is at the closest position via the module connection harness 62. In addition, the module 53 is connected to the joint portion 12C which is at the closest position via the module connection harness 63, the module 54 is connected to the joint portion 12D which is at the closest position via the module connection harness 64, and the module 55 is connected to the joint portion 12E which is at the closest position via the module connection harness 65. Furthermore, the module 56 is connected to the joint portion 12F which is at the closest position via the module connection harness 66, the module 57 is connected to the joint portion 12G which is at the closest position via the module connection harness 67, and the module 58 is connected to the joint portion 12H which is at the closest position via the module connection harness 68.

In other words, since all of the shapes and the functions of the plurality of joint portions 12A to 12H on the wire harness main body 10 are common, when each module (51 to 58) is connected to the wire harness main body 10, it is possible to select and connect the joint portion which is at the closest position in distance among the joint portions.

Therefore, since it is possible to connect each of the module connection harnesses 61 to 68 by the shortest distance, it is possible to minimize the length. In addition, since the plurality of joint portions 12A to 12H are installed at a constant interval (L), for example, even when the positions at which each of the modules (51 to 58) is disposed are changed in accordance with a change in specification to be deviated in a horizontal direction (horizontal direction in FIG. 3) of the vehicle body, the connection can be performed by the shortest distance if the joint portions (12A to 12H) of the connection point are changed. Therefore, even when there is no particular room for length of each of the module connection harnesses 61 to 68, it is possible to reliably perform the connection with a sufficient length of wiring.

<Configuration Example of Electric Circuit>

A configuration example of an electric circuit of a main portion of the electrical system is illustrated in FIG. 1. In the electrical system of FIG. 1, similar to the example of FIG. 2, one end of the wire harness main body 10 is connected to the power source control box 21, and the other end of the wire harness main body 10 is connected to the power source control box 22. In other words, the four wires 11a, 11b, 11c, and 11d of the wire harness main body 10 are respectively connected to the power source control boxes 21 and 22.

In addition, in the joint portion 12A, the wires which are branched from each of the four wires 11a to 11d are connected to the four connection terminals of the connector 13A. Similarly, in the joint portions 12B, 12C, 12D, 12E, 12F, 12G, and 12H, the wires which are branched from each of the four wires 11a to 11d are respectively connected to the four connection terminals of the connectors 13B, 13C, 13D, 13E, 13F, 13G, and 13H.

The power source control box 21 illustrated in FIG. 1 has an electronic control unit (ECU) 21a which has a function of controlling the module of the body system embedded therein. In addition, the power source control box 22 illustrated in FIG. 1 has an electronic control unit (ECU) 22a which has a function of controlling the module of the travelling system and the audio system of the vehicle embedded therein. Each of the electronic control units 21a and 22a is configured of a microcomputer which has a communication function.

In addition, the power source control box 21 includes a power source terminal 21b, an earth terminal 21c, and a communication terminal 21d, and the power source control box 22 includes a power source terminal 22b, an earth terminal 22c, and a communication terminal 22d. The power source terminal 21b and the earth terminal 21c of the power source control box 21 are connected to a main power source 30 on the vehicle side, and the communication terminal 21d of the power source control box 21 is connected to a host ECU 40 on the vehicle side. Connection is also similarly performed in the power source control box 22. The main power source 30 is configured to correspond to a power source circuit, such as an alternator (generator) or a main battery, which is mounted on the vehicle. The host ECU 40 is an electronic control unit (ECU) which controls an engine or the like on the vehicle side.

Therefore, the power source control boxes 21 and 22 can supply the power supplied from the main power source 30 to each of the modules 51 to 58 from each of the joint portions (12A to 12H) via the wire harness main body 10. In addition, the electronic control unit 21a in the power source control box 21 can control the module of the body system among each of the modules 51 to 58 which is connected to each of the joint portions (12A to 12H). In addition, the electronic control unit 22a in the power source control box 22 can control the module of the travelling system and the audio system of the vehicle among each of the modules 51 to 58 which is connected to each of the joint portions (12A to 12H).

In addition, the wire harness main body 10 illustrated in FIGS. 1 and 2 is configured by tying up the four wires 11a to 11d in a bundle, but the number of wires can be further reduced. For example, it is also possible to use the power transfer wire 11a for communication, and if the wire 11a is used for bilateral communication, the wires 11c and 11d are unnecessary.

<Appearance of Power Source Control Box>

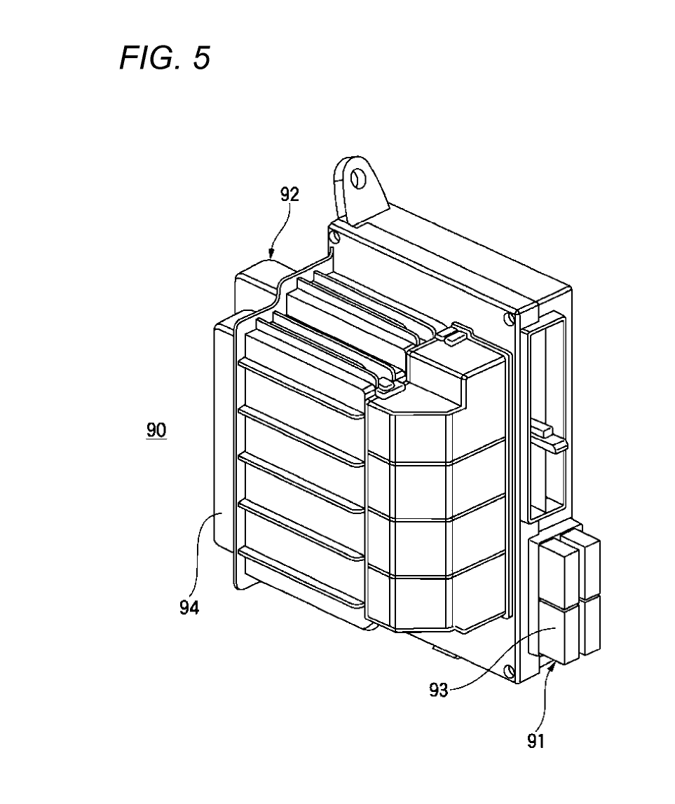

A specific example of appearance of the power source control box is illustrated in FIG. 5. A power source control box 90 illustrated in FIG. 5 has an electronic control portion 91 which has a function of controlling the module of the body system, and an electronic control portion 92 which controls the module of the travelling system and the audio system of the vehicle, embedded therein. In addition, the power source control box 90 includes an output side connection portion 93 which can be connected to one end of the wire harness main body 10, and an input side connection portion 94 which can be further connected to the main power source 30 and the host ECU 40.

The power source control box 90 illustrated in FIG. 5 can be used as the power source control boxes 21 and 22 illustrated in FIG. 1. The plurality of electronic control portions 91 and 92 may be embedded in one power source control box 90 as illustrated in FIG. 5, and each one of the electronic control units (21a, 22a) may be embedded in the plurality of power source control boxes 21 and 22 as illustrated in FIG. 1.

<Advantages of Above-Described Electrical System>

For example, in the electrical system illustrated in FIG. 3, each of the multiple modules 51 to 58 can commonly use one group of wires (11a to 11d) in the wire harness main body 10 for power supply and communication. Therefore, even when the number of connected modules increases, it is not necessary to increase the number of wires (11a to 11d) which configure the wire harness main body 10. For this reason, it is possible to prevent the thickness of the external shape of the wire harness main body 10 from increasing, and also to reduce the weight thereof.

In addition, the plurality of joint portions (12A to 12H) are formed at a constant interval (L) on the wire harness main body 10 as illustrated in FIG. 2, the connectors (13A to 13H) and the connection terminal which have the common shape and the function are formed in the joint portions. Therefore, when each of the multiple modules 51 to 58 are connected to the wire harness main body 10 as illustrated in FIG. 3, it is possible to connect each of the modules by the shortest distance via the module connection harnesses (61 to 68).

Furthermore, even when the positions at which each of the modules 51 to 58 is disposed are changed in accordance with the change in specification or the like, it is possible to select and connect the joint portion which is at the closest position of a change point among the plurality of joint portions (12A to 12H). For this reason, even when there is not enough room for the length of the module connection harnesses (61 to 68), it is possible to reliably perform the connection. For this reason, a degree of freedom regarding the positions at which each module is disposed increases.

In addition, as illustrated in FIGS. 2 and 3, it is desirable that the plurality of power source control boxes 21 and 22 are provided, one end of the wire harness main body 10 is connected to the power source control box 21, and the other end of the wire harness main body 10 is connected to the power source control box 22. Accordingly, it is possible to shorten the distance from each of the power source control boxes 21 and 22 to the loads in each of the modules (51 to 58), and to reduce the voltage drop in the power supply wires (11a, 11b). For this reason, it is possible to make the diameter of the wire and the wire harness main body 10 thin.

Here, characteristics of the embodiment of the above-described electrical system according to the present invention are briefly summarized and listed in each of the following [1] to [3].

[1] The electrical system including: the modules (50A to 50D) which have at least one of the switch (502), the sensor (503), the load (504), and the relay (505) embedded therein; the power source box portions (power source control boxes 21 and 22) which supply power to the modules; and the wire harness (15) which connects the plurality of modules and the power source box portion to each other, in which the power source box portion, includes the electronic control portions (ECU-A, ECU-B) that communicates with the module and controls the module, in which the module includes a communication portion (ECU in the E connector portion 501) that communicates with the electronic control portion, in which the wire harness is configured by tying up plural wires, including the power source line that transfers the power and the communication line that transfers the signal, in a bundle, and in which joint portions (12A, 12B, 12C, 12D, 12E, 12F, 12G, 12H) that are formed as each of the plural wires of the wire harness is branched and can be connected to the module, are formed at a plurality of locations on the wire harness at a substantially constant interval, in the wire harness.

[2] The electrical system described in [1], further including: a first power source box portion (power source control box 21) and a second power source box portion (power source control box 22) as parts of the power source box portion, in which one end of the wire harness is connected to the first power source box portion, and the other end of the wire harness is connected to the second power source box portion.

[3] The electrical system described in [2], in which each of the joint portions is made as each of the plural wires of the wire harness is branched and extended, and is connected with connectors (13A, 13B, 13C, 13D, 13E, 13F, 13G, 13H) that include the communication portion on the extended wires, and in which the communication portion communicates with the electronic control portion when the connector is connected in the module.

The present invention is described with reference the detailed or specific embodiment, but it is apparent for those skilled in the art that various changes or modifications can be added without departing from the spirit and the scope of the present invention.

The present application is based on Japanese Patent Application No. 2013-055420 filed on Mar. 18, 2013, and the content thereof is incorporated herein by reference.

### INDUSTRIAL APPLICABILITY

According to an electrical system of the present invention, even when the number of modules including loads that consume a large amount of power increases, it is possible to supply a sufficient amount of power to each module, and to suppress an increase in the size or the weight of the external shape of the wire harness used in wiring. The present invention having such effects is efficient regarding the electrical system in which the plurality of modules are connected to each other via the wire harness similarly to those of an onboard electrical system.

### REFERENCE SIGNS LIST

10 WIRE HARNESS MAIN BODY
11a, 11b, 11c, 11d WIRE
12A, 12B, 12C, 12D, 12E, 12F, 12G, 12H JOINT PORTION
13A, 13B, 13C, 13D, 13E, 13F, 13G, 13H CONNECTOR
15 WIRE HARNESS
21, 22 POWER SOURCE CONTROL BOX
21a, 22a ELECTRONIC CONTROL UNIT
30 MAIN POWER SOURCE
40 HOST ECU
51 to 58 MODULE
61 to 68 MODULE CONNECTION HARNESS
70 REINFORCE
50A, 50B, 50C, 50D MODULE
501 E CONNECTOR PORTION
502 SWITCH
503 SENSOR
504 LOAD
505 RELAY

1. An electrical system comprising:
a module which includes at least one of a switch, a sensor, a load, and a relay embedded therein:
a power source box portion which supplies power to the module; and
a wire harness which connects the plurality of modules and the power source box portion to each other, wherein
the power source box portion includes an electronic control portion that communicates with the module and controls the module,
the module includes a communication portion that communicates with the electronic control portion,
the wire harness is configured by tying up plural wires, including a power source line that transfers the power and a communication line that transfers a signal, in a bundle, and
joint portions, formed as each of the plural wires of the wire harness is branched and configured to be connected to the module, are formed at a plurality of locations on the wire harness at a substantially constant interval, in the wire harness.

2. The electrical system as set forth in claim 1, comprising:
a first power source box portion and a second power source box portion as parts of the power source box portion,
wherein one end of the wire harness is connected to the first power source box portion, and the other end of the wire harness is connected to the second power source box portion.

3. The electrical system as set forth in claim 2, wherein
each of the joint portions is made as each of the plural wires of the wire harness is branched and extended, and a connector that includes the communication portion on the extended wires is connected thereto, and
the communication portion communicates with the electronic control portion when the connector is connected in the module.
